(19) United States
(12) Patent Application Publication
(10) Pub. No.: US 2017/0212221 A1
(43) Pub. Date: Jul. 27, 2017

(54) PHOTOELECTRIC CONVERSION APPARATUS AND INFORMATION PROCESSING APPARATUS

(71) Applicant: CANON KABUSHIKI KAISHA, Tokyo (JP)

(72) Inventors: Tatsuhito Goden, Machida-shi (JP); Hajime Ikeda, Yokohama-shi (JP); Keisuke Ota, Tokyo (JP); Yoichi Wada, Yokohama-shi (JP); Toshinori Hasegawa, Yokohama-shi (JP)

(21) Appl. No.: 15/400,131

(22) Filed: Jan. 6, 2017

(30) Foreign Application Priority Data
Jan. 25, 2016 (JP) 2016-011883

(51) Int. Cl. G01S 7/481; G01S 17/06; H01L 27/146

(52) U.S. Cl. CPC G01S 7/4816; H01L 27/14612; H01L 27/14643; G01S 17/06

(57) ABSTRACT

A photoelectric conversion apparatus, comprising first and second photoelectric conversion portions, a charge holding portion, and first and second transferring portions for transferring charges generated in the first and second photoelectric conversion portions, respectively, to the charge holding portion, wherein a first ratio is a ratio of an amount of electrons transferred by the first transferring portion to an amount of the electrons generated in the first photoelectric conversion portion, a second ratio is a ratio of an amount of holes transferred by the second transferring portion to an amount of the holes generated in the second photoelectric conversion portion, and a ratio of the first ratio to the second ratio is lower than a ratio of mobility of electrons to mobility of holes.

### BACKGROUND OF THE INVENTION

Field of the Invention

The present invention relates to a photoelectric conversion apparatus and an information processing apparatus.

Description of the Related Art

There is a distance measurement method called a TOF (Time Of Flight) method that irradiates a target object with light and detects reflected light from the target object, thereby measuring the distance to the target object. More specifically, the distance to the target object is measured based on the time from the timing of light irradiation to the timing of reflected light detection (that is, the delay amount of the reflected light with respect to the irradiation light) and the speed of light. Since the reflected light from the target object is detected together with ambient light that is light in the external environment, a technique of measuring the distance in consideration of the ambient light is demanded.

FIG. 9 shows an example of the arrangement of a photoelectric conversion apparatus 1 according to the second embodiment (from paragraph 0092) of Japanese Patent Laid-Open No. 2005-303268. The photoelectric conversion apparatus 1 includes a first light detecting portion 11a, a hole holding portion 13 and a gate portion 38a corresponding to the first light detecting portion 11a, a second light detecting portion 11b, an electron holding portion 14 and a gate portion 38b corresponding to the second light detecting portion 11b, a recombining portion 15, and an output portion 16. Holes (holes corresponding to ambient light) generated by the light detecting portion 11a in an OFF state of a light source 2 are transferred to the hole holding portion 13 via the gate portion 38a and held. Electrons (electrons corresponding to both ambient light and reflected light from a target object 3) generated by the light detecting portion 11b in an ON state of the light source 2 are transferred to the electron holding portion 14 via the gate portion 38b and held. The recombining portion 15 recombines the holes (holes corresponding to ambient light) in the hole holding portion 13 and the electrons (electrons corresponding to both ambient light and reflected light) in the electron holding portion 14. Accordingly, electrons corresponding to the reflected light out of the reflected light and the ambient light remain. The electrons are read out by the output portion 16. According to this method, a signal corresponding to the reflected light out of the reflected light and the ambient light can be obtained.

As an example of a detailed arrangement for implementing the above-described function, two photoelectric conversion portions (for example, photodiodes) may be used as the light detecting portions 11a and 11b. In addition, a PMOS transistor may be used as the gate portion 38a that transfers holes, and an NMOS transistor may be used as the gate portion 38b that transfers electrons. That is, holes are transferred from one photoelectric conversion portion (light detecting portion 11a) to the hole holding portion 13 by the PMOS transistor (gate portion 38a), and electrons are transferred from the other photoelectric conversion portion (light detecting portion 11b) to the electron holding portion 14 by the NMOS transistor (gate portion 38b).

The mobility of holes is smaller than that of electrons. A difference can be generated between the transfer rate of holes from the light detecting portion 11a to the hole holding portion 13 and that of electrons from the light detecting portion 11b to the electron holding portion 14. For this reason, if the transfer period of electrons and holes is shortened, a difference is generated between the transfer amount of holes in the hole holding portion 13 and that of electrons in the electron holding portion 14 as well.

The transfer amount difference may lead to an error in a signal based on the difference between the electron generation amount and the hole generation amount. This may lower distance measurement accuracy when performing distance measurement based on the TOF method, as in, for example, Japanese Patent Laid-Open No. 2005-303268.

### SUMMARY OF THE INVENTION

The present invention provides a technique advantageous in reducing errors in a signal based on electrons and holes.

One of the aspects of the present invention provides a photoelectric conversion apparatus, comprising a first photoelectric conversion portion, a second photoelectric conversion portion, a charge holding portion configured to hold electric charges, a first transferring portion configured to transfer electrons generated in the first photoelectric conversion portion to the charge holding portion, and a second transferring portion configured to transfer holes generated in the second photoelectric conversion portion to the charge holding portion, wherein when a ratio of an amount of electrons transferred by the first transferring portion to an amount of the electrons generated in the first photoelectric conversion portion is defined as a first ratio, and a ratio of an amount of holes transferred by the second transferring portion to an amount of the holes generated in the second photoelectric conversion portion is defined as a second ratio, the first photoelectric conversion portion, the second photoelectric conversion portion, the first transferring portion, and the second transferring portion are configured such that a ratio of the first ratio to the second ratio becomes lower than a ratio of mobility of electrons to mobility of holes.

Further features of the present invention will become apparent from the following description of exemplary embodiments with reference to the attached drawings.

### BRIEF DESCRIPTION OF THE DRAWINGS

FIG. 1 is a block diagram for explaining an example of the arrangement of an imaging apparatus;

FIG. 2 is a block diagram for explaining an example of the arrangement of a detector;

FIG. 3 is a circuit diagram for explaining an example of the arrangement of a pixel;

FIGS. 4A to 4D are timing charts for explaining an example of a pixel driving method;

FIGS. 5A to 5D are views for explaining a reference example of the structure of a pixel;

FIGS. 6A to 6C are views for explaining examples of the structure of a pixel;

FIG. 7 is a view for explaining an example of the structure of a pixel;

FIGS. 8A to 8D are views for explaining an example of the structure of a pixel; and

FIG. 9 is a view for explaining the arrangement of a reference example.

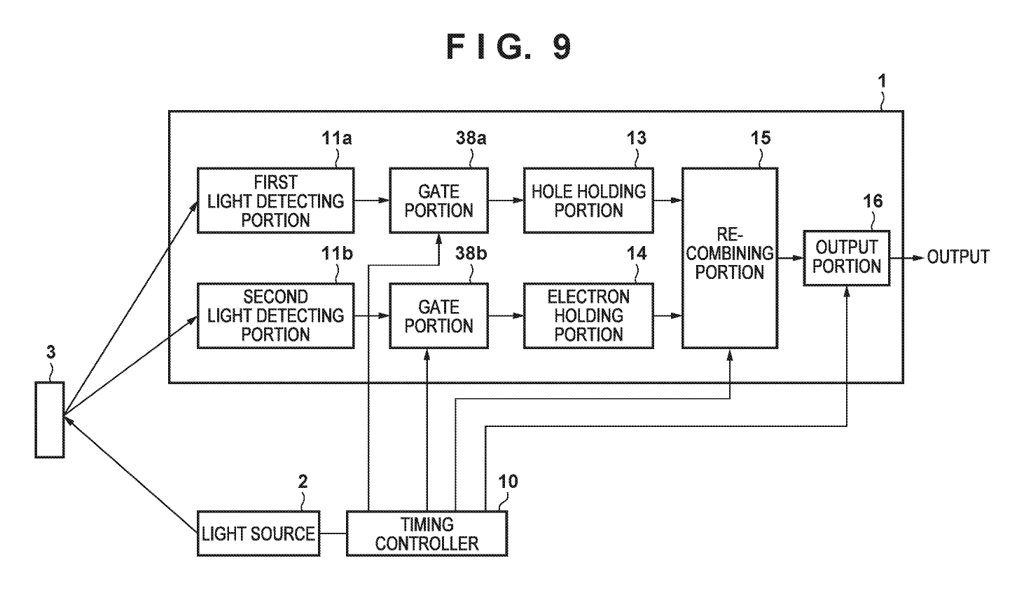

### DESCRIPTION OF THE EMBODIMENTS

Preferred embodiments of the present invention will now be described with reference to the accompanying drawings. Note that the drawings only aim at explaining structures or arrangements, and the dimensions of members illustrated do not necessarily reflect real dimensions. The same reference numerals denote constituent elements having the same functions throughout the drawings, and a repetitive description thereof will be omitted.

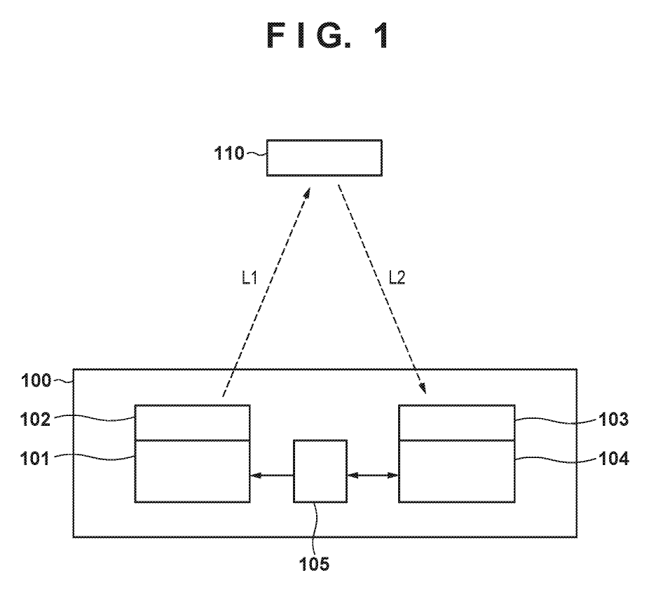

FIG. 1 is a block diagram for explaining an example of the arrangement of an information processing system 100 (to be referred to as a system 100 hereinafter) to which a photoelectric conversion apparatus according to the present invention is applied. The system 100 includes, for example, a light source 101 such as an LED, optical systems 102 and 103 such as a lens, a detector 104, and a processor 105.

Light L1 emitted by the light source 101 irradiates a target object 110 as a distance measurement target via the optical system 102. Light L2 includes reflected light from the target object 110, and enters the detector 104 via the optical system 103. The detector 104 supplies a signal based on the light L2 to the processor 105. The detector 104 corresponds to the photoelectric conversion apparatus according to the present invention, and can be referred to as a photodetecting apparatus or simply as a semiconductor apparatus (note that the apparatus may be called a device, a module, or the like). The processor 105 drives the light source 101 and the detector 104, and calculates the distance to the target object 110 based on the signal from the detector 104 or acquires information based on the distance (a detailed method will be described later).

Note that the arrangement of the system 100 is not limited to this example. The arrangement may partially be modified in accordance with the purpose, or elements may be added in association. For example, the system 100 can be an imaging apparatus (camera), and the detector 104 can function as an imaging unit. In another example, the system 100 can be a distance measurement apparatus.

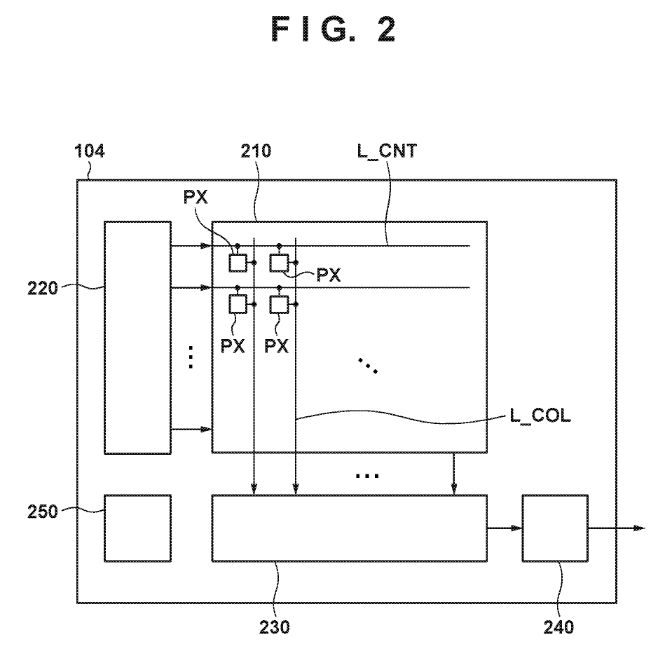

FIG. 2 is a block diagram for explaining an example of the arrangement of the detector 104. The detector 104 includes, for example, a pixel array 210, a driving unit 220, a readout unit 230, an output unit 240, and a controller 250. The pixel array 210 can include a plurality of pixels PX arranged in an array (to form a plurality of rows and a plurality of columns) on a semiconductor substrate.

In this specification, assuming that the system 100 is an imaging apparatus, the expression “pixel” is used. However, “photodetecting unit”, “light receiving unit”, or “sensor unit” may be used in place of “pixel”. These may simply generally be referred to as “unit”. “Pixel array” may be expressed as “unit array”.

The driving unit 220, for example, drives each pixel PX of the pixel array 210 using a control line L_CNT arranged on each row. The driven pixel PX outputs a signal according to the light L2 as a pixel signal via a column signal line L_COL. The readout unit 230 horizontally transfers the pixel signal output via the column signal line L_COL. The output unit 240 outputs the horizontally transferred pixel signal to the processor 105 described above. The controller 250 controls the units based on a reference signal such as a clock signal. The detector 104 may further include a power supply unit (not shown) that supplies power to at least one of the driving unit 220, the readout unit 230, the output unit 240, and the controller 250 described above.

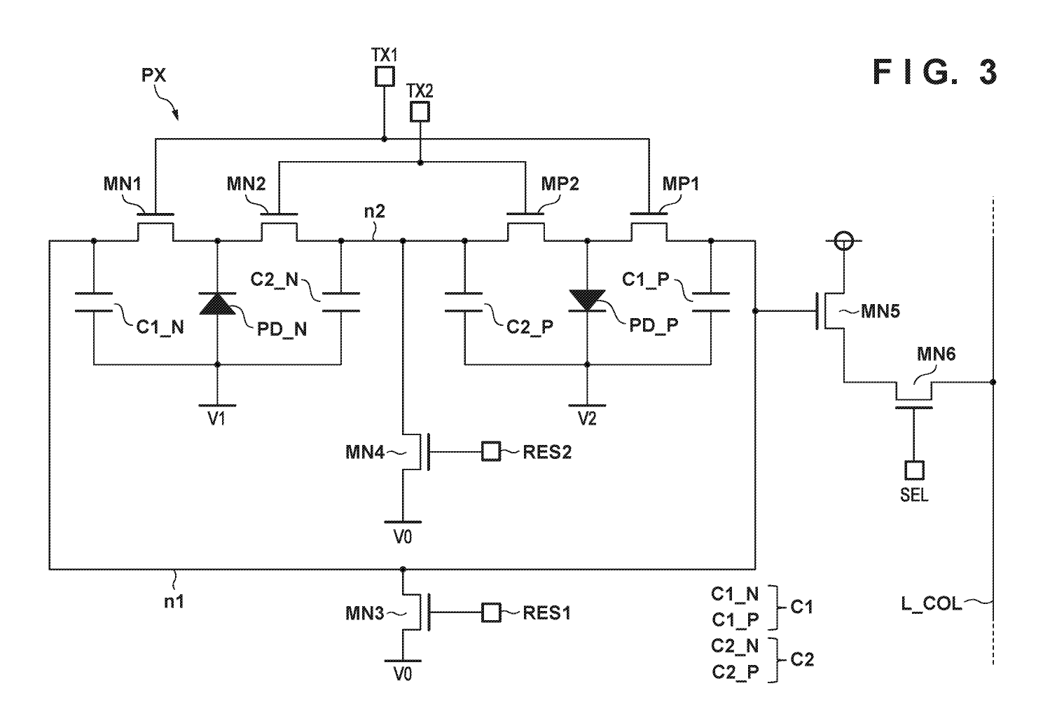

FIG. 3 is a circuit diagram for explaining an example of the arrangement of the unit pixel PX. The pixel PX includes, for example, photodiodes PD_N and PD_P, transistors MN1 to MN6, MP1, and MP2, and capacitors C1_N, C2_N C_P, and C2_P.

The NMOS transistor MN1 is arranged to form a current path between a node n1 and the cathode of the photodiode PD_N corresponding to a first photoelectric conversion portion. The anode of the photodiode PD_N is fixed to a voltage V1 (that is, connected to a power supply line configured to apply the voltage V1). The PMOS transistor MP1 is arranged to form a current path between the node n1 and the anode of the photodiode PD_P corresponding to a second photoelectric conversion portion. The cathode of the photodiode PD_P is fixed to a voltage V2. In this example, the voltage V1 can be set to about −2[V], and the voltage V2 can be set to about +2[V].

The NMOS transistor MN2 is arranged to form a current path between a node n2 and the cathode of the photodiode PD_N. The PMOS transistor MP2 is arranged to form a current path between the node n2 and the anode of the photodiode PD_P.

The capacitors C1_N and C2_N can be formed from an n-type semiconductor region and a p-type semiconductor region surrounding it (details will be described later). One terminal of the capacitor C1_N is connected to the node n1, and the other terminal of the capacitor C1_N is fixed to the voltage V1. One terminal of the capacitor C2_N is connected to the node n2, and the other terminal of the capacitor C2_N is fixed to the voltage V1. The capacitors C1_P and C2_P can be formed from a p-type semiconductor region and an n-type semiconductor region surrounding it (details will be described later). One terminal of the capacitor C1_P is connected to the node n1, and the other terminal of the capacitor C1_P is fixed to the voltage V2. One terminal of the capacitor C2_P is connected to the node n2, and the other terminal of the capacitor C2_P is fixed to the voltage V2.

The capacitor C1_N and C1_P are discriminately illustrated here. They may be referred to as a “capacitor C1” altogether. That is, the capacitor C1_N and C1_P are separately illustrated here because they can be discriminated from the viewpoint of structure. However, the capacitors may be combined and equivalently regarded as a single capacitance component because they are both fixed to a constant voltage on the side opposite to the node n1. The capacitor C1_N holds electrons generated by photoelectric conversion in the photodiode PD_N, and the capacitor C1_P holds holes generated by photoelectric conversion in the photodiode PD_P. Hence, the capacitor C1 that is the composite capacitor of the capacitors C1_N and C1_P holds electric charges in an amount corresponding to the difference between the amount of electrons and the amount of holes. A potential difference (voltage) based on (amount of electric charges)/(capacitance value of capacitor C1) is generated in the capacitor C1. The capacitor C1 may be referred to as a “charge holding portion” configured to hold electric charges from the photodiode or a “voltage holding portion” configured to hold a voltage corresponding to the amount of the electric charges. Similarly, the capacitor C2_N and C2_P may be referred to as a “capacitor C2” altogether. The capacitor C2 may be referred to as a charge holding portion or a voltage holding portion.

A control signal TX1 is supplied to the gates of the transistors MN1 and MP1 via the control line L_CNT. For example, when the control signal TX1 has high level, the transistor MN1 is in the conductive state, whereas the transistor MP1 is in the non-conductive state. For example, when the control signal TX1 has low level, the transistor MN1 is in the non-conductive state, whereas the transistor MP1 is in the conductive state. Similarly, a control signal TX2 is supplied to the gates of the transistors MN2 and MP2 via the control line L_CNT.

The transistor MN3 is arranged to form a current path between the node n1 and the power supply line of a voltage V0. A control signal REST is supplied to the gate of the transistor MN3 via the control line L_CNT. The transistor MN3 initializes the capacitors C1_N and C1_P in response to the control signal RES1. Similarly, the transistor MN4 is arranged to form a current path between the node n2 and the power supply line of the voltage V0, and initializes the capacitors C2_N and C2_P in response to a control signal RES2. In this example, the voltage V0 can be set to 0[V].

Note that in this example, a form in which the control signals RES1 and RES2 that are different from each other are supplied to the transistors MN3 and MN4 has been exemplified. In another example, a common control signal may be supplied to them. In this example, a form in which both the transistors MN3 and MN4 are fixed to the voltage V0 has been exemplified. In another example, they may be fixed to voltages that are different from each other.

The transistor MN5 performs a source follower operation in accordance with the voltage of the node n1. In response to a control signal SEL supplied via the control line L_CNT, the transistor MN6 outputs a signal according to the voltage of the source of the transistor MN5 to the column signal line L_COL as a pixel signal. The transistors MN5 and MN6 correspond to a readout unit configured to read out (or output) a pixel signal. In this example, NMOS transistors are used as both transistors. However, PMOS transistors may be used. The readout unit functions as a circuit unit configured to output the pixel signal outside the pixel, and may be referred to as an output unit or the like.

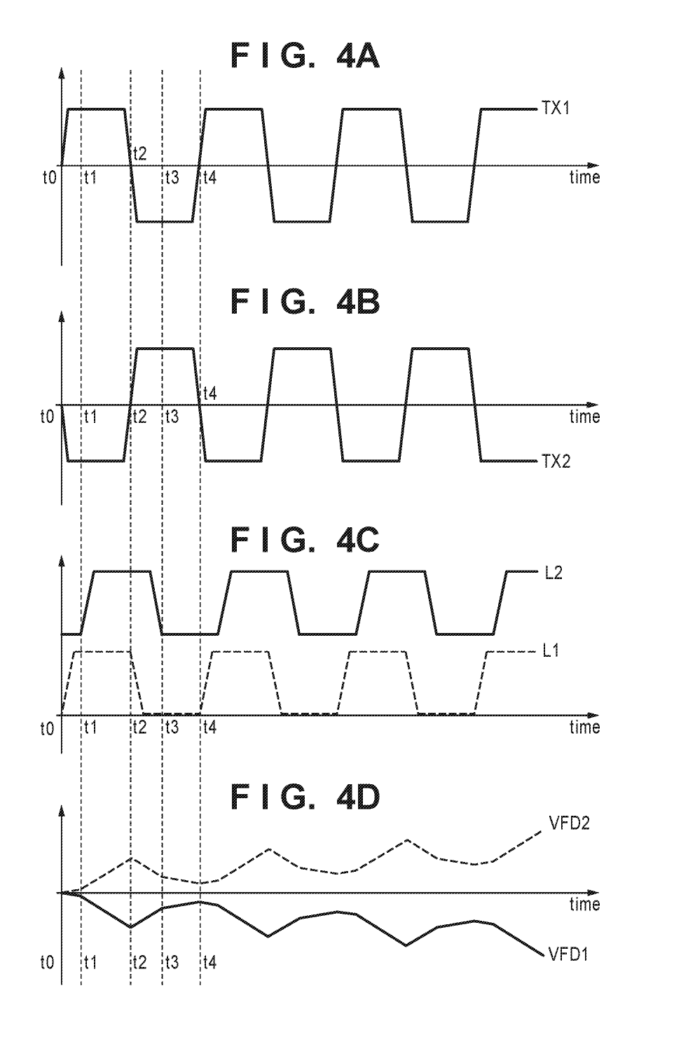

FIGS. 4A to 4D are timing charts for explaining an example of the driving method of the unit pixel PX in distance measurement based on the TOF method (the abscissa represents time). FIGS. 4A and 4B show the waveforms of the control signals TX1 and TX2, respectively (the ordinate represents the signal level). When the signal TX1 has high level (positive voltage), the transistor MN1 is in the conductive state, and the transistor MP1 is in the non-conductive state. When the signal TX1 has low level (negative voltage), the transistor MP1 is in the conductive state, and the transistor MN1 is in the non-conductive state. Note that if the signal TX1 is 0[V], both the transistors MN1 and MP1 are in the non-conductive state. This also applies to the signal TX2.

FIG. 4C shows the light amount waveform of the light L1 and that of the light L2 (the ordinate represents the light amount). As described above, the light L1 is light generated by the light source 101. As shown in FIG. 4C, the light source 101 is repetitively turned on and off at a predetermined period. The light L2 is light received by the detector 104. The light L2 can include not only reflected light from the target object 110 but also ambient light that is light in the external environment. For this reason, for the received light L2, FIG. 4C shows a low level that is not 0 and corresponds to the OFF state of the light source 101 and a high level that is higher than the low level and corresponds to the ON state of the light source 101. A delay (phase difference) with respect to the light L1, which corresponds to the distance to the target object 110, occurs in the received light L2.

As is apparent from FIGS. 4A to 4C, the high level/low level period of the signals TX1 and TX2 synchronizes with the ON/OFF period of the light source 101. In this example, switching of the conductive state/non-conductive state of each of the transistors MN1, MN2, MP1, and MP2 which receive the signal TX1 or TX2 is done almost at the same time as ON/OFF switching of the light source 101. Note that in this example, the time of one period is 10 [nsec] or less (for example, 0.1 [nsec] to 10 [nsec]).

FIG. 4D shows a voltage VFD1 of the node n1 (more specifically, the voltage of the capacitors C1_N and C1_P) and a voltage VFD2 of the node n2 (more specifically, the voltage of the capacitors C2_N and C2_P) (the ordinate represents the voltage value). That is, the voltage VFD1 corresponds to the charge amount held by the capacitor C1, and the voltage VFD2 corresponds to the charge amount held by the capacitor C2.

First (before time t0), the transistors MN3 and MN4 initialize the capacitors C1_N and C1_P and the capacitors C2_N and C2_P, that is, the voltages VFD1 and VFD2. In this example (V0=[V], V1=−2[V], and V2=+2[V]), the initial value of the voltages VFD1 and VFD2 is almost 0[V]. Simultaneously, the transistors MN1 and MN2 and the transistors MP1 and MP2 are set in the conductive state, thereby initializing the photodiodes PD_N and PD_P. For example, the cathode voltage of the photodiode PD_N after the initialization is about −1 [V], and the anode voltage of the photodiode PD_P after the initialization is about +1[V].

At the time t0, the light source 101 is turned on. At the time t0, the signal TX1 goes high, and the signal TX2 goes low. The transistors MN1 and MP2 change to the conductive state, and the transistors MN2 and MP1 change to the non-conductive state. That is, the photodiode PD_N is connected to the capacitor C1_N by the transistor MN1, and the photodiode PD_P is connected to the capacitor C2_P by the transistor MP2. At time t1 after that, the received light L2 goes high.

In the period of the time t0 to t1, since the received light L2 has low level (not 0), electrons that are generated in the photodiode PD_N (and can be accumulated in association) and correspond to the light amount of the light L2 at low level are transferred to the capacitor C1_N. Similarly, holes that are generated in the photodiode PD_P and correspond to the light amount of the light L2 at low level are transferred to the capacitor C1_P. Hence, as shown in FIG. 4D, at the time t1, the voltage VFD1 changes to a voltage according to the transferred electrons, and similarly, the voltage VFD2 changes to a voltage according to the transferred holes.

At the time t1, the received light L2 goes high. Hence, the generation amount of electrons in the photodiode PD_N and the generation amount of holes in the photodiode PD_P from the time t1 (up to time t2 to be described later) are larger than those in the period of the time t0 to t1. That is, the change amounts of the voltages VFD1 and VFD2 in the period of the time t1 to t2 are larger than those in the period of the time t0 to t1.

At the time t2, the light source 101 is turned off. At the time t2, the signal TX1 goes low, and the signal TX2 goes high. The transistors MN1 and MP2 change to the non-conductive state, and the transistors MN2 and MP1 change to the conductive state. That is, the photodiode PD_N is connected to the capacitor C2_N by the transistor MN2, and the photodiode PD_P is connected to the capacitor C1_P by the transistor MP1.

Accordingly, from the time t2 (up to time t3 to be described later), holes that are generated in the photodiode PD_P and correspond to the light amount of the light L2 at high level are transferred to the capacitor C1_P. The holes transferred to the capacitor C1_P and the electrons transferred to the capacitor C1_N in the period of the time t0 to t2 are recombined and disappear. For this reason, the voltage VFD1 rises (since the capacitors C1_N and C1_P correspond to the single capacitor C1, as described above, the voltage VFD1 can simply be said to be raised by the transfer of holes to the capacitor C1). Similarly, from the time t2 to t3, electrons that are generated in the photodiode PD_N and correspond to the light amount of the light L2 at high level are transferred to the capacitor C2_N, and the voltage VFD2 lowers.

After that, at the time t3, the received light L2 goes low. Hence, the generation amount of electrons in the photodiode PD_N and the generation amount of holes in the photodiode PD_P from the time t3 (up to time t4 to be described later) are smaller than those in the period of the time t2 to t3. That is, the change amounts of the voltages VFD1 and VFD2 in the period of the time t3 to t4 are smaller than those in the period of the time t2 to t3.

At the time t4, the light source 101 is turned on again. The signal TX1 goes high, and the signal TX2 goes low. That is, defining the time t0 to t4 as one period, the above-described series of operations are periodically repeated from the time t4. As described above, the time of one period is 10 [nsec] or less and ranges, for example, from 0.1 [nsec] to 10 [nsec].

When the above-described series of operations are repeated (that is, electron transfer and hole transfer are alternately performed, and the electrons and holes are recombined), the voltage VFD1 (VFD2) gradually shifts from the initial value (0 [V] in this example). For example, if the delay amount of the received light L2 with respect to the light L1 is small (letting T be the period of the above-described series of operations, if the delay amount is smaller than T/4), as in the example of FIG. 4C, the voltage VFD1 lowers (the voltage VFD2 rises). On the other hand, if the delay amount of the received light L2 with respect to the light L1 is large (if the delay amount is larger than T/4), the voltage VFD1 rises (the voltage VFD2 lowers). If the delay amount of the received light L2 with respect to the light L1 is almost equal to T/4, the voltage VFD1 (VFD2) almost maintains the initial value (0 [V] in this example). It is therefore possible to calculate the distance to the target object 110 based on the voltage VFD1 (VFD2) after the repetition of the above-described series of operations, that is, perform distance measurement based on the TOF method.

Here, consider a case in which the operating frequency is relatively high, that is, the period T of the series of operations is, for example, 10 [nsec] or less, as described above. When the pixel PX is driven at a high frequency, the detection accuracy of the shift amount of the voltage VFD1 (VFD2) becomes high, and the accuracy of distance measurement (particularly, the accuracy of distance measurement in a case in which the distance to the distance measurement target is short) can be improved. Note that the frequency may be set higher according to size reduction of the pixel PX.

In this example, a form in which a signal according to the voltage VFD1 is read out as a pixel signal by the transistors MN5 and MN6 has been exemplified. In another example, a signal according to the voltage VFD2 may be read out. When reading out a signal according to only one of the voltages VFD1 and VFD2, transistors that are not used for the readout in the transistors MN1 to MN4 and the transistors MP1 and MP2 need not be arranged. In still another example, it may be possible to read out both a signal according to the voltage VFD1 and a signal according to the voltage VFD2 and improve the S/N ratio using both signals.

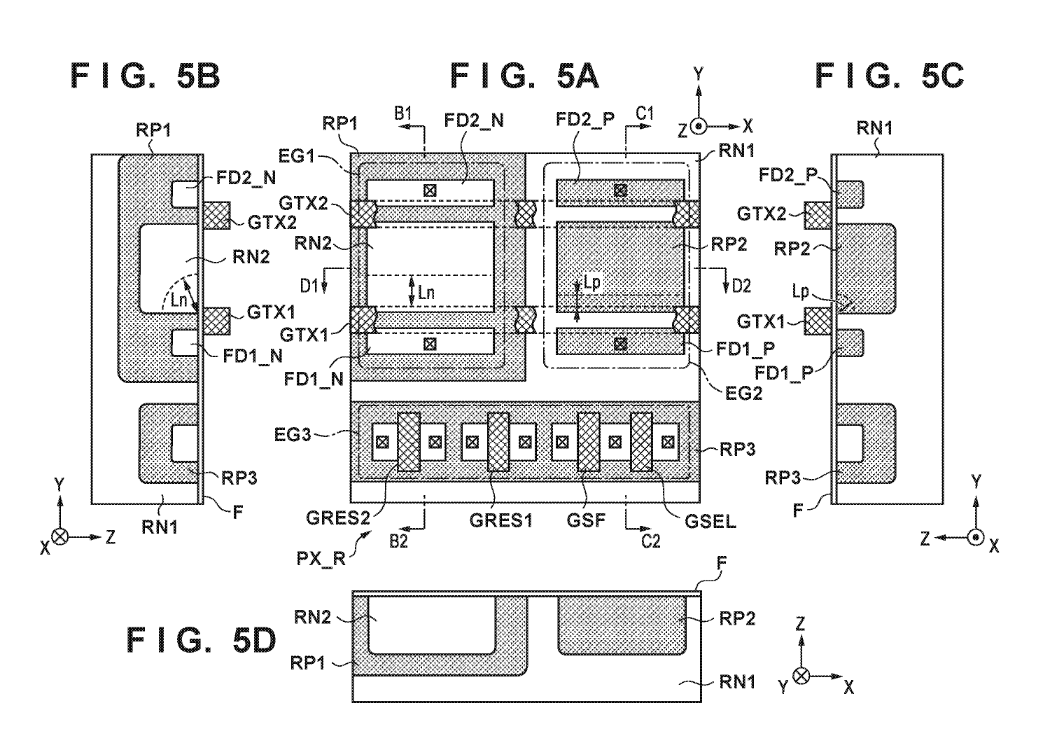

A reference example will be explained below with reference to FIGS. 5A to 5D before a description of several preferred examples of the present invention (for easy understanding of the examples). FIG. 5A is a schematic view for explaining the layout of the pixel PX (to enable a distinction from a pixel to be described later, the pixel PX of this layout will be referred to as a “pixel PX_R”) on a planar view (a planar view of the upper surface of the semiconductor substrate or a plane parallel to it; to be simply referred to as a “planar view” hereinafter). FIG. 5B is a schematic view showing a sectional structure taken along a cut line B1-B2. FIG. 5C is a schematic view showing a sectional structure taken along a cut line C1-C2. FIG. 5D is a schematic view showing a sectional structure taken along a cut line D1-D2. For easy understanding of the structure, the correspondence relationship between the drawings is shown using an X direction (corresponding to a first direction), a Y direction (corresponding to a second direction), and a Z direction that intersects a plane formed by the X and Y directions. Note that the X direction and the Y direction correspond to the row direction and the column direction of the above-described pixel array 210, respectively.

For example, a p-type semiconductor region RP1 is formed in an n-type semiconductor region RN1 that is at least part of the semiconductor substrate. Here, “formed in the n-type region RN1” means “surrounded by the n-type region RN1”. That is, the p-type region RP1 is surrounded by the n-type region RN1. This also applies to the following explanation of other regions.

The photodiode PD_N, the transistors MN1 and MN2, and the capacitors C1_N and C2_N described above are formed in the p-type region RP1. For example, the photodiode PD_N is formed by forming an n-type semiconductor region RN2 in the p-type region RP1. Electrons generated by photoelectric conversion mainly collect in the n-type region RN2. The capacitor C1_N is formed by forming an n-type floating diffusion FD1_N in the p-type region RP1. Similarly, the capacitor C2_N is formed by forming an n-type floating diffusion FD2_N in the p-type region RP1.

Note that the n-type region RN2 that is the cathode of the photodiode PD_N corresponds to the source of the transistor MN1 (integrates with the source), and the floating diffusion FD2_N corresponds to the drain of the transistor MN1 (integrates with the drain). From this viewpoint, the transistor MN1 that is a charge transfer MOS transistor may be expressed as a transferring portion. This also applies to the transistors MN2, MP1, and MP2. The driving unit 220 supplies the control signal TX1 to the transistors MN1 and MP1 and supplies the control signal TX2 to the transistors MN2 and MP2, and may therefore be expressed as a signal supply unit.

An electrode GTX1 corresponding to the gate of the transistor MN1 is arranged between the floating diffusion FD1_N and the n-type region RN2 in the planar view on an insulating film F formed on the semiconductor substrate. Similarly, an electrode GTX2 corresponding to the gate of the transistor MN2 is arranged between the floating diffusion FD2_N and the n-type region RN2 in the planar view on the insulating film F formed on the semiconductor substrate.

The photodiode PD_P, the transistors MP1 and MP2, and the capacitors C1_P and C2_P described above are formed in the n-type region RN1. For example, the photodiode PD_P is formed by forming a p-type semiconductor region RP2 in the n-type region RN1. Holes generated by photoelectric conversion mainly collect in the p-type region RP2. The capacitor C1_P is formed by forming a p-type floating diffusion FD1_P in the n-type region RN1. Similarly, the capacitor C2_P is formed by forming a p-type floating diffusion FD2 P in the n-type region RN1. The electrode GTX1 corresponds to not only the gate of the transistor MN1 but also the gate of the transistor MP1. That is, the gate of the transistor MN1 and the gate of the transistor MP1 are commonly formed by the electrode GTX1. Similarly, the electrode GTX2 corresponds to the gate of the transistor MP2 as well.

Note that the gate electrode GTX1 (GTX2) need not always be formed commonly. Electrodes corresponding to the transistors MN1 and MP1 (MN2 and MP2) may be formed individually. When the gate electrodes GTX1 (GTX2) are individually formed, the gate capacitance can be made small, leading to advantage in speeding up the drive of the pixel PX (raising the operating frequency).

The elements (the photodiode PD_N, the transistors MN1 and MN2, and the capacitors C1_N and C2_N ) formed in the p-type region RP1 are arranged along the Y direction. For example, the photodiode PD_N is arranged between the capacitors C1_N and C2_N. The capacitor C1_N as the readout target is located on the side where the transistors MN3 to MN6 (to be described later) are arranged, and the capacitor C2_N is located on the opposite side. However, they may be replaced with each other. The transistor MN1 is arranged between the capacitor C1_N and the photodiode PD_N, and the transistor MN2 is arranged between the capacitor C2_N and the photodiode PD_N. These elements are shown as a “first element group EG1” in FIG. 5A.

This also applies to the elements (the photodiode PD_P, the transistors MP1 and MP2, and the capacitors C1_P and C2_P) formed in the n-type region RN1. These elements are shown as a “second element group EG2” in FIG. 5A.

As is apparent from FIG. 5A, the element groups EG1 and EG2 are arranged in the X direction in correspondence with each other. That is, the photodiode PD_N, the transistors MN1 and MN2, and the capacitors C1_N and C2_N can be arranged to be next to the photodiode PD_P, the transistors MP1 and MP2, and the capacitors C1_P and C2_P, respectively, in the X direction.

Elements and portions corresponding to the transistors MN3 to MN6 are arranged at positions further spaced apart in the Y direction from the positions where the above-described element groups EG1 and RG2 are arranged. Electrodes GRES1, GRES2, GSF, and GSEL shown in FIG. 5A correspond to the gates of the transistors MN3, MN4, MN5, and MN6, respectively. These elements are shown as a “third element group EG3” in FIG. 5A. Note that a p-type region RP3 shown in FIGS. 5B and 5C corresponds to the p-type wells of the transistors MN3 to MN6. In this example, a form in which the p-type regions RP1 and RP3 are independent of each other (isolated by the n-type region RN1) is shown. However, they may be integrated.

The element groups EG1, EG2, and EG3 can be electrically separated from each other by a p-n junction. In this example, the p-n junction is formed by the p-type region RP1 and the n-type region RN1 in the X and Y directions and by the n-type region RN1 and the p-type region RP3 in the Y direction. The electrical separation by the p-n junction can be attained by a potential barrier formed between two regions of different conductivity types. An intrinsic region (i-type region) may exist between the two regions.

Consider a case in which the pixel PX_R is driven at the above-described frequency (for example, a relatively high frequency with a period T of 10 [nsec] or less) to improve the distance measurement accuracy in the structure of the reference example shown in FIGS. 5A to 5D. In this case, electrons generated in the photodiode PD_N (holes generated in the photodiode PD_P) may not be sufficiently transferred to the capacitor C1 (C2).

More specifically, referring to FIGS. 4A to 4D and FIGS. 5A to 5D, assume that the period (that is, the time t0 to t2) in which a high-level voltage is applied to the electrode GTX1 is relatively short, for example, 5 [nsec] or less. In this case, of the electrons collected in the n-type region RN2, only some electrons on the side of the electrode GTX1 can be transferred to the floating diffusion FD1_N. More specifically (as schematically shown to facilitate understanding), only electrons in a region represented by a distance Ln in FIGS. 5A and 5B can be transferred to the floating diffusion FD1_N. The distance Ln is the distance from an n-channel region (the cannel region of the transistor MN1) formed by applying a high-level voltage to the electrode GTX1, and can correspond to the average moving distance of electrons in the period (time t0 to t2). In other words, the distance Ln can correspond to the width and depth of a region of the n-type region RN2, in which the electrons capable of reaching the channel region in the period (time t0 to t2) exist. The distance Ln can mainly be calculated based on the period (time t0 to t2), the mobility of electrons in the n-type region RN2, and the electric field near the electrode GTX1 in the n-type region RN2. For example, if the mobility of electrons is 1350 [cm²/V·sec], the electric field (average) in the n-type region RN2 is 10 to 50 [kV/m], and the period of the time t0 to t2 is 1 [nsec], the distance Ln is about 1.4 to 6.8 [μm]. If the period of the time t0 to t2 is 0.1 to 10 [nsec], the distance Ln is about 0.1 to 70 [μm].

Similarly, assume that the period (that is, the time t2 to t4) in which a low-level voltage is applied to the electrode GTX1 is relatively short. In this case, of the holes collected in the p-type region RP2, only some holes on the side of the electrode GTX1 (only holes in a region represented by a distance Lp in FIGS. 5A and 5C) can be transferred to the floating diffusion FD1_P. The distance Lp is the distance from the cannel region of the transistor MP1 formed by applying a low-level voltage to the electrode GTX1, and can correspond to the average moving distance of holes in the period (time t2 to t4). The distance Lp can mainly be calculated based on the period (time t2 to t4), the mobility of holes in the p-type region RP2, and the electric field near the electrode GTX1 in the p-type region RP2. For example, if the mobility of holes is 480 [cm²/V·sec], the electric field (average) in the p-type region RP2 is 10 to 50 [kV/m], and the period of the time t2 to t4 is 1 [nsec], the distance Lp is about 0.5 to 2.4 [μm]. If the period of the time t2 to t4 is 0.1 to 10 [nsec], the distance Lp is about 0.05 to 25 [μm].

That is, according to the structure of the reference example, the volume (the volume represented by Ln or Lp) capable of transferring electric charges in the n-type region RN2 and that in the p-type region RP2 are different from each other. For this reason, the transfer efficiency of electrons from the photodiode PD_N (that is, the transfer efficiency of electrons by the transistor MN1) and the transfer efficiency of holes from the photodiode PD_P (that is, the transfer efficiency of holes by the transistor MP1) can be different from each other.

In this specification, the expression “transfer efficiency” is used for the descriptive convenience. However, the transfer efficiency of electrons can be obtained by the ratio of the transfer rate of generated electrons by the transistor MN1 (the transfer amount of electrons per unit time) to the amount of the generated electrons. That is, letting Q be the amount of generated electrons, and S be the transfer rate of the generated electrons, a transfer efficiency E of the electrons is given by E=S/Q. The transfer amount of electrons per unit time can be obtained by dividing the amount of electrons actually transferred during the transfer period (the time t0 to t2 in the above-described example) by the transfer period. The amount of actually transferred electrons can be obtained based on the variation amount of the voltage VFD1 of the capacitor C1 and the capacitance value of the capacitor C1. According to these definitions, the transfer efficiency E of electrons is almost constant independently of the amount of generated electrons. Hence, for the photodiode PD_N and the transistor MN1, for example, if the transfer rate when electrons of a charge amount Q1 [C] are generated is S1 [C/sec], a transfer rate S2 when electrons of a charge amount Q2 [C] are generated can be S2=S1×(Q2/Q1). This also applies to the transfer efficiency of holes.

According to the structure of the reference example, for example, even if the amount of electrons collected in the n-type region RN2 almost equals the amount of holes collected in the p-type region RP2, the actual transfer amounts are different from each other. As a result, although the amount of electrons collected in the n-type region RN2 almost equals the amount of holes collected in the p-type region RP2, the voltage VFD1 of the node n1 described with reference to FIGS. 3 and 4D shifts. Additionally, for example, even if the amount of electrons collected in the n-type region RN2 and the amount of holes collected in the p-type region RP2 are different from each other, an error (an error from the amount to be actually shifted) may occur in the shift amount of the voltage VFD1. These may cause lowering of the accuracy of distance measurement (see FIGS. 4A to 4D) based on the above-described TOF method.

In the present invention, the pixel PX is configured such that the ratio of the transfer efficiency of electrons to that of holes becomes lower than the ratio of the mobility of electrons to that of holes. In other words, this can be expressed as follows. That is, the ratio of the amount of electrons transferred by the transistor MN1 or MN2 (first transferring portion) in the amount of electrons generated by the photodiode PD_N (first photoelectric conversion portion) is defined as a first ratio. The ratio of the amount of holes transferred by the transistor MP1 or MP2 (second transferring portion) in the amount of holes generated by the photodiode PD_P (second photoelectric conversion portion) is defined as a second ratio. At this time, the transistors MN1, MN2, MP1, and MP2 are configured such that the ratio of the first ratio to the second ratio becomes lower than the ratio of the mobility of electrons to that of holes.

For example, as one form, the pixel PX is configured such that the volume capable of transferring electric charges in the n-type region RN2 and that in the p-type region RP2 become equal to each other. In still another form, concerning the transistors (MN1, MP1, and the like) that transfer electrons, the pixel PX is configured such that the driving force of the transistor MP1 becomes larger than that of the transistor MN1. According to these arrangement examples, the transfer efficiency of electrons from the photodiode PD_N and that of holes from the photodiode PD_P can be made closer. Ideally, they can be made equal to each other.

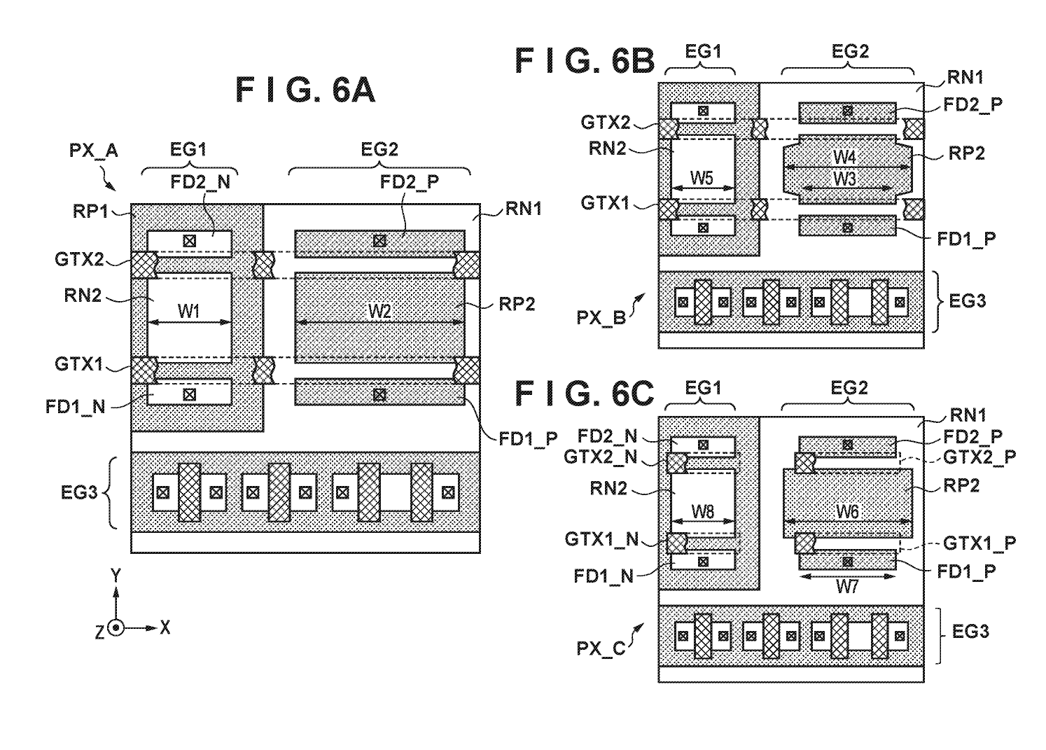

FIG. 6A is a schematic view for explaining a first example of the pixel structure according to the present invention, like FIG. 5A of the reference example. The pixel PX of this example will be referred to as a “pixel PX_A” so as to be discriminated from the pixel PX_R of the reference example. According to the pixel PX_A, when the width of the n-type region RN1 (the width in the X direction (that is, the direction intersecting the electron transfer direction); it should be noted that “intersect” means “actually being orthogonal”, and this also applies to the other widths) is defined as a width W1, and the width of the p-type region RP2 is defined as a width W2, W2>W1 holds. This is equivalent to making the volume capable of transferring electric charges in the p-type region RP2 close to that in the n-type region RN2. According to the pixel PX_A, the channel width of the transistors MP1 and MP2 is made larger than that of the transistors MN1 and MN2. This is equivalent to making the driving force (typically, the current amount in the conductive state) of the transistors MP1 and MP2 close to that of the transistors MN1 and MN2.

Since the mobility of electrons is about three times higher than that of holes (the mobility can change depending on the impurity concentration in the semiconductor), the width W2 is preferably about three times larger than the width W1. For example, the width W2 preferably falls within the range of about 1.5 to 5 times larger than the width W1 (1.5×W1≦W2≦5×W1). For example, when a semiconductor of a typically impurity concentration is used, the width W2 preferably falls within the range of about 2 to 4 times larger than the width W1 (2×W1≦W2≦4×W1).

This can make the volume capable of transferring electric charges in the n-type region RN2 and that in the p-type region RP2 described with reference to the distances Ln and Lp in FIG. 5A equal (or close) to each other. More specifically, the width (area) of the region represented by the distance Ln in the n-type region RN2 and the width (area) of the region represented by the distance Lp in the p-type region RP2 can be made equal to each other. The transfer efficiency of electrons from the photodiode PD_N and that of holes from the photodiode PD_P thus become equal to each other. The ratio of the transfer efficiency of electrons to that of holes is preferably close to 1 as much as possible. The ratio falls within the range of, for example, 0.8 to 1.2, and preferably, within the range of 0.95 to 1.05.

According to the pixel PX_A, for example, if the amount of electrons collected in the n-type region RN2 almost equals the amount of holes collected in the p-type region RP2, the actual transfer amounts are almost equal to each other. Hence, the voltage VFD1 does not shift actually. Additionally, for example, if the amount of electrons collected in the n-type region RN2 and the amount of holes collected in the p-type region RP2 are different from each other, errors that may occur in the shift amount of the voltage VFD1 can be reduced. Hence, according to the pixel PX_A, the accuracy of distance measurement based on the TOF method can be raised as compared to the pixel PX_R of the above-described reference example.

FIG. 6B is a schematic view showing a second example of the pixel structure according to the present invention. The pixel PX of this example will be referred to as a “pixel PX_B”. In the pixel PX_B, the p-type region RP2 has a width W3 at the ends (near the electrodes GTX1 and GTX2) and a width W4 (>W3) at the center (a portion between the electrodes GTX1 and GTX2 spaced apart from the ends). That is, the p-type region RP2 is formed to be wider as the distance from the electrode GTX1 or GTX2 increases. When the width of the n-type region RN2 is defined as a width W5, the width W4 is preferably about three times larger than the width W5, as in the first example. For example, 1.5×W5≦W4≦5≦W5 preferably holds. Typically, 2×W5≦W4≦4×W5 preferably holds.

This structure can also make the volume capable of transferring electric charges in the n-type region RN2 and that in the p-type region RP2 equal (or close) to each other, and the same effect as that of the pixel PX_A of the above-described first example can be obtained. The widths W3 and W4 of the p-type region RP2 may either steeply increase as in this example or moderately increase as the distance from the electrode GTX1 (or GTX2) increases.

Note that since it is only necessary that the volume capable of transferring electric charges in the n-type region RN2 and that in the p-type region RP2 become equal to each other, concerning the width W3, W3>W5 suffices. However, W3<W5 or W3=W5 may hold. If W3=W5, the channel width of the transistors MP1 and MP2 and that of the transistors MN1 and MN2 are equal to each other. In this case, the driving force of the transistors MP1 and MP2 and that of the transistors MN1 and MN2 are different from each other. This is equivalent to making the transfer efficiency of electric charges by the transistors MN1 and MN2 and the transfer efficiency of electric charges by the transistors MP1 and MP2 equal to each other.

FIG. 6C is a schematic view showing a third example of the pixel structure according to the present invention. The pixel PX of this example will be referred to as a “pixel PX_C”. In the pixel PX_C, electrodes GTX1_N and GTX1_P are arranged in place of the electrode GTX1, and electrodes GTX2_N and GTX2_P are arranged in place of the electrode GTX2. The electrodes GTX1_N and GTX1_P correspond to the gates of the transistors MN1 and MP1, respectively. The electrodes GTX2_N and GTX2_P correspond to the gates of the transistors MN2 and MP2, respectively. A width W6 of the p-type region RP2 is larger than the width of the electrodes GTX1_P and GTX2_P. A width W7 of the floating diffusions FD1_P and FD2_P is smaller than the width of the electrodes GTX1_P and GTX2_P. When the width of the n-type region RN2 is defined as a width W8, the width W6 is preferably about three times larger than the width W8, as in the first example. For example, 1.5×W8≦W6≦5×W8 preferably holds. Typically, 2×W8≦W6≦4×W8 preferably holds.

According to this structure, the same effect as that of the pixel PX_A of the above-described first example can be obtained. Additionally, the gate capacitance of the transistors MN1, MN2, MP1, and NP2 can be made small. Hence, according to the pixel PX_C, it is possible to further raise the operating frequency and advantageously improve the accuracy of distance measurement based on the TOF method, as compared to the pixel PX_A of the first example.

Note that concerning the width W7, W7>W8 suffices. However, W7<W8 or W7=W8 may hold. If W7=W8, the channel width of the transistors MP1 and MP2 and that of the transistors MN1 and MN2 are equal to each other. In this case, the driving force of the transistors MP1 and MP2 and that of the transistors MN1 and MN2 are different from each other. This is equivalent to making the transfer efficiency of electric charges by the transistors MN1 and MN2 and the transfer efficiency of electric charges by the transistors MP1 and MP2 equal to each other.

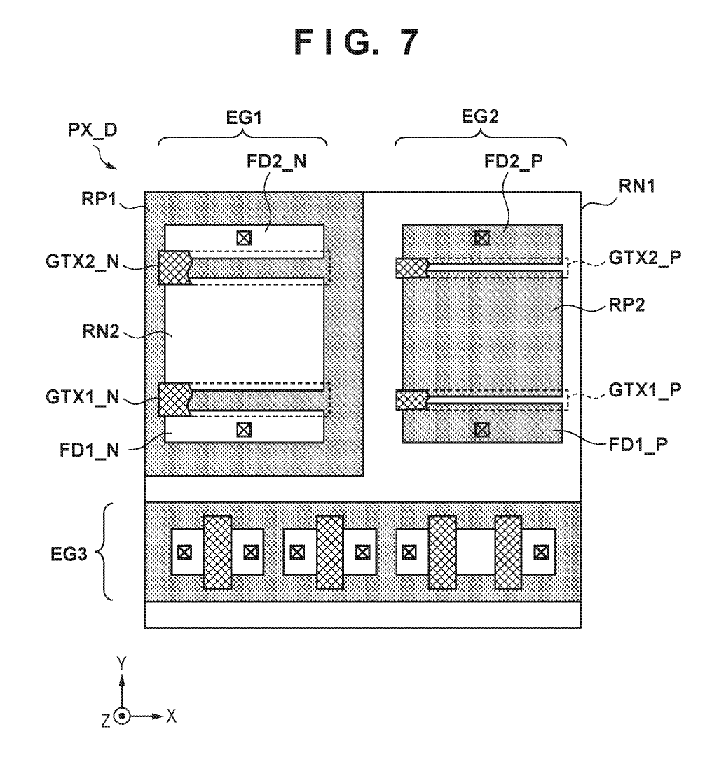

FIG. 7 is a schematic view showing a fourth example of the pixel structure according to the present invention. The pixel PX of this example will be referred to as a “pixel PX_D”. In the pixel PX_D, the electrodes GTX1_N and GTX1_P are arranged in place of the electrode GTX1, and the electrodes GTX2_N and GTX2 P are arranged in place of the electrode GTX2. The size of the electrodes GTX1_P and GTX2_P in the Y direction (that is, the channel length of the transistors MP1 and MP2) is smaller than the size of the electrodes GTX1_N and GTX2_N in the Y direction (that is, the channel length of the transistors MN1 and MN2).

When the channel length of the transistors MP1 and MP2 is decreased, the driving force of the transistors MP1 and MP2 improves. Hence, their hole transfer efficiency itself can improve. Hence, the pixel PX_D is more advantageous in improving the accuracy of distance measurement based on the TOF method.

In the fourth example, a form in which the channel length of the transistors MP1 and MP2 is decreased has been exemplified. The same effect can also be obtained by adjusting another parameter of the transistors MP1 and MP2. For example, the thickness of the gate insulating film of the transistors MP1 and MP2 may be decreased such that, for example, the driving force of the transistors MP1 and MP2 becomes almost equal to that of the transistors MN1 and MN2. In another example, the absolute value of the threshold voltage of the transistors MP1 and MP2 may be made smaller than the absolute value of the threshold voltage of the transistors MN1 and MN2. In still another example, the conduction time (the conductive state time/period T) of the transistors MP1 and MP2 may be made longer than the conduction time of the transistors MN1 and MN2 (that is, the duty ratio in one cycle from the time t0 to t4 (see FIG. 4) may be adjusted). In yet another example, the amplitude (pulse height) of the signal (or the voltage of the signal) supplied to the transistors MP1 and MP2 may be made larger than the amplitude of the signal (or the voltage of the signal) supplied to the transistors MN1 and MN2. Two or more of these conditions may be combined.

In the fourth example, the width of the n-type region RN2 and that of the p-type region RP2 can be almost equal to each other but may be different from each other (that is, the features of the first to third examples may be combined with the fourth example).

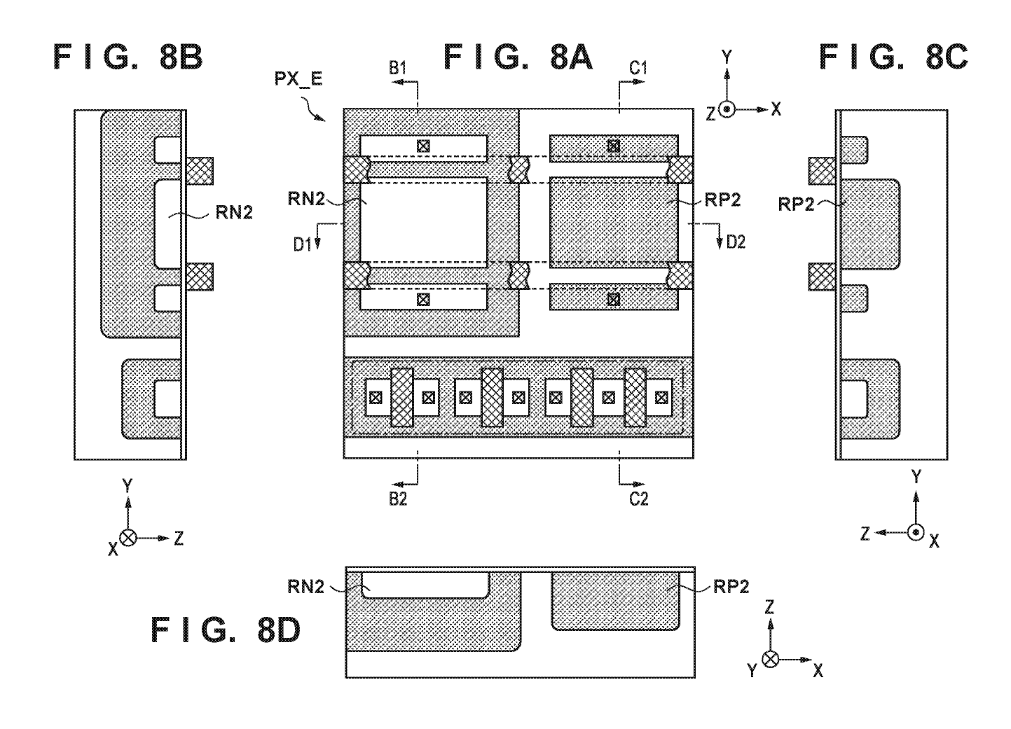

FIGS. 8A to 8D are schematic views showing a fifth example of the pixel structure according to the present invention, like FIGS. 5A to 5D of the reference example. The pixel PX of this example will be referred to as a “pixel PX_E”. In the pixel PX_E, the depth of the n-type region RN2 (the depth from the upper surface of the semiconductor substrate) is made smaller than the depth of the p-type region RP2 such that the transfer efficiency of electrons from the photodiode PD_N matches the transfer efficiency of holes from the photodiode PD_P. In other words, the depth of the p-type region RP2 is larger than the depth of the n-type region RN2. Preferably, the depth of the n-type region RN2 is smaller than the above-described distance Ln. Even this structure can make the volume capable of transferring electric charges in the n-type region RN2 and that in the p-type region RP2 equal (or close) to each other, and can obtain the same effect as that of the pixel PX_A of the first example.

Several preferred forms have been described above. However, the present invention is not limited to these examples, and may partially be changed or replaced without departing from the scope of the present invention.

In this specification, the system 100 as an application example of the present invention has been exemplified as an imaging apparatus. However, the present invention is usable for another application purpose, as a matter of course, and is not limited to the form exemplified here. For example, the present invention may be applied to a motion sensor or an obstacle sensor that can be mounted on a vehicle or the like, or may be applied to a game machine for implementing a virtual space. Additionally, for example, the present invention is applicable not only to the structure configured to perform distance measurement based on the TOF method but also to a structure configured to adjust a focal point based on a phase difference detection method.

The terms used in this specification are merely used for the purpose of explaining the present invention. Obviously, the present invention is not limited to the strict meanings of the terms, and can also include equivalent terms.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-011883, filed on Jan. 25, 2016, which is hereby incorporated by reference herein in its entirety.

What is claimed is:

1. A photoelectric conversion apparatus comprising:
a first photoelectric conversion portion;
a second photoelectric conversion portion;
a charge holding portion configured to hold electric charges;
a first transferring portion configured to transfer electrons generated in the first photoelectric conversion portion to the charge holding portion; and
a second transferring portion configured to transfer holes generated in the second photoelectric conversion portion to the charge holding portion,
wherein when a ratio of an amount of electrons transferred by the first transferring portion to an amount of the electrons generated in the first photoelectric conversion portion is defined as a first ratio, and
a ratio of an amount of holes transferred by the second transferring portion to an amount of the holes generated in the second photoelectric conversion portion is defined as a second ratio,
the first photoelectric conversion portion, the second photoelectric conversion portion, the first transferring portion, and the second transferring portion are configured such that a ratio of the first ratio to the second ratio becomes lower than a ratio of mobility of electrons to mobility of holes.

2. The apparatus according to claim 1, wherein the ratio of the first ratio to the second ratio falls within a range of 0.8 to 1.2.

3. The apparatus according to claim 1, further comprising a substrate with which the first and second photoelectric conversion portions are provided,
wherein the first photoelectric conversion portion comprises a first photodiode including an n-type semiconductor region and a p-type semiconductor region,
the second photoelectric conversion portion comprises a second photodiode including a p-type semiconductor region and an n-type semiconductor region, and
the first photodiode and the second photodiode are configured to meet
a condition that in a planar view of an upper surface of the substrate, a width of the p-type semiconductor region of the second photodiode in a direction intersecting a transfer direction of the holes in the second transferring portion is larger than a width of the n-type semiconductor region of the first photodiode in a direction intersecting a transfer direction of the electrons in the first transferring portion, and/or
a condition that a depth of the p-type semiconductor region of the second photodiode from the upper surface of the substrate is larger than a depth of the n-type semiconductor region of the first photodiode from the upper surface.

4. The apparatus according to claim 3, wherein a ratio of the width of the second photodiode to the width of the first photodiode falls within a range of 1.5 to 5, and
a ratio of the depth of the second photodiode to the depth of the first photodiode falls within a range of 1.5 to 5.

5. The apparatus according to claim 1, further comprising a substrate with which the first and second photoelectric conversion portions are provided,
wherein the second photoelectric conversion portion comprises a second photodiode including a p-type semiconductor region and an n-type semiconductor region, and
in a planar view of an upper surface of the substrate, the p-type semiconductor region of the second photodiode is arranged such that a width in a direction intersecting a transfer direction of the second transferring portion becomes large as a distance from the second transferring portion increases.

6. The apparatus according to claim 1, further comprising a substrate with which an NMOS transistor and a PMOS transistor are provided,
wherein the first transferring portion is included in the NMOS transistor, and the second transferring portion is included in the PMOS transistor, and
the NMOS transistor and the PMOS transistor are configured to meet
a condition that a channel width of the PMOS transistor is larger than a channel width of the NMOS transistor,
a condition that a channel length of the PMOS transistor is smaller than a channel length of the NMOS transistor,
a condition that a thickness of a gate insulating film of the PMOS transistor is smaller than a thickness of a gate insulating film of the NMOS transistor, and/or
a condition that an absolute value of a threshold voltage of the PMOS transistor is smaller than an absolute value of a threshold voltage of the NMOS transistor.

7. The apparatus according to claim 1, further comprising a driving unit configured to alternately drive the first transferring portion and the second transferring portion,
the driving unit driving the first transferring portion and the second transferring portion at a period of not more than 10 [nsec].

8. The apparatus according to claim 1, further comprising a driving unit configured to alternately drive the first transferring portion and the second transferring portion at a predetermined period,
the driving unit driving the first transferring portion and the second transferring portion during a time corresponding to one period such that a time in which the second transferring portion is driven becomes longer than a time in which the first transferring portion is driven.

9. The apparatus according to claim 1, further comprising a signal supply unit configured to supply a signal to each of the first transferring portion and the second transferring portion,
wherein an amplitude of the signal supplied to the second transferring portion is larger than an amplitude of the signal supplied to the first transferring portion.

10. The apparatus according to claim 1, wherein the electrons transferred by the first transferring portion and the holes transferred by the second transferring portion are recombined in the charge holding portion, and
the photoelectric conversion apparatus further comprises a readout unit configured to read out, from the charge holding portion, a signal according to an amount of electric charges remaining after the recombination.

11. The apparatus according to claim 1, further comprising a substrate with which the first and second photoelectric conversion portions, the first and second transferring portions and the charge holding portion are provided,
wherein the charge holding portion includes an n-type semiconductor region to which the electrons generated in the first photoelectric conversion portion are transferred by the first transferring portion, and a p-type semiconductor region to which the holes generated in the second photoelectric conversion portion are transferred by the second transferring portion, and
in a planar view of an upper surface of the substrate,
the first photoelectric conversion portion, the first transferring portion, and the n-type semiconductor region of the charge holding portion are arranged along a first direction,
the second photoelectric conversion portion, the second transferring portion, and the p-type semiconductor region of the charge holding portion are arranged along the first direction,
the first photoelectric conversion portion and the second photoelectric conversion portion are arranged in a second direction intersection the first direction,
the first transferring portion and the second transferring portion are arranged in the second direction, and
the n-type semiconductor region of the charge holding portion and the p-type semiconductor region of the charge holding portion are arranged in the second direction.

12. The apparatus according to claim 1, wherein a plurality of units each including the first photoelectric conversion portion, the second photoelectric conversion portion, the charge holding portion, the first transferring portion, and the second transferring portion are arranged in an array.

13. A photoelectric conversion apparatus comprising:
a first photodiode including an n-type semiconductor region and a p-type semiconductor region arranged in a substrate;
a second photodiode including a p-type semiconductor region and an n-type semiconductor region arranged in the substrate;
a charge holding portion configured to hold electric charges;
an NMOS transistor having the n-type semiconductor region of the first photodiode as a source and configured to transfer electrons generated in the first photodiode to the charge holding portion, and
a PMOS transistor having the p-type semiconductor region of the second photodiode as a source and configured to transfer holes generated in the second photodiode to the charge holding portion,
wherein the first photodiode and the second photodiode are configured to meet
a condition that in a planar view of an upper surface of the substrate, a width of the p-type semiconductor region of the second photodiode in a direction intersecting a transfer direction of the holes in the PMOS transistor is larger than a width of the n-type semiconductor region of the first photodiode in a direction intersecting a transfer direction of the electrons in the NMOS transistor, and/or
a condition that a depth of the p-type semiconductor region of the second photodiode from the upper surface of the substrate is larger than a depth of the n-type semiconductor region of the first photodiode from the upper surface.

14. A photoelectric conversion apparatus comprising:
a first photodiode including an n-type semiconductor region and a p-type semiconductor region arranged in a substrate;
a second photodiode including a p-type semiconductor region and an n-type semiconductor region arranged in the substrate;
a charge holding portion configured to hold electric charges;
an NMOS transistor having the n-type semiconductor region of the first photodiode as a source and configured to transfer electrons generated in the first photodiode to the charge holding portion, and
a PMOS transistor having the p-type semiconductor region of the second photodiode as a source and configured to transfer holes generated in the second photodiode to the charge holding portion,
wherein the NMOS transistor and the PMOS transistor are configured to meet
a condition that a channel width of the PMOS transistor is larger than a channel width of the NMOS transistor,
a condition that a channel length of the PMOS transistor is smaller than a channel length of the NMOS transistor,
a condition that a thickness of a gate insulating film of the PMOS transistor is smaller than a thickness of a gate insulating film of the NMOS transistor, and/or
a condition that an absolute value of a threshold voltage of the PMOS transistor is smaller than an absolute value of a threshold voltage of the NMOS transistor.

15. An information processing system comprising:
a photoelectric conversion apparatus of claim 1; and
a processor configured to process a signal output from the photoelectric conversion apparatus.
